(19) United States
(12) Patent Application Publication
(10) Pub. No.: US 2024/0364302 A1
(43) Pub. Date: Oct. 31, 2024

(54) ACOUSTIC WAVE MODULE

(71) Applicant: Murata Manufacturing Co., Ltd., Nagaokakyo-shi (JP)

(72) Inventor: Takashi IWAMOTO, Nagaokakyo-shi (JP)

(21) Appl. No.: 18/766,890

(22) Filed: Jul. 9, 2024

Related U.S. Application Data
(63) Continuation of application No. PCT/JP2023/002433, filed on Jan. 26, 2023.

(30) Foreign Application Priority Data
Feb. 24, 2022 (JP) 2022-026659

(51) Int. Cl. H03H 9/02; H03H 9/10

(52) U.S. Cl. CPC H03H 9/02574; H03H 9/02834; H03H 9/1092

(57) ABSTRACT

An acoustic wave module includes a hollow space defined by first and second piezoelectric bodies, a support layer, and a first functional element. A second functional element and a shield layer are disposed in the hollow space. The shield layer includes first and second layers disposed on the first functional element side and a second layer disposed on the second functional element side. The second layer adds, to the first layer, a force that causes the first layer to warp so that the first layer at a peripheral end portion and a peripheral end portion approaches the first functional element.

### CROSS REFERENCE TO RELATED APPLICATIONS

This application claims the benefit of priority to Japanese Patent Application No. 2022-026659, filed on Feb. 24, 2022, and is a Continuation Application of PCT Application No. PCT/JP2023/002433, filed on Jan. 26, 2023. The entire contents of each application are hereby incorporated herein by reference.

### BACKGROUND OF THE INVENTION

### 1. Field of the Invention

The present invention relates to acoustic wave modules including acoustic wave devices, and more particularly to acoustic wave modules including a functional element and a shield that covers the functional element.

### 2. Description of the Related Art

An acoustic wave module including an acoustic wave device including a surface acoustic wave (SAW) resonator or a bulk acoustic wave (BAW) resonator is used in an electronic device such as a cellular phone or a smartphone. Japanese Unexamined Patent Application Publication No. 2000-236230 describes a surface acoustic wave filter in which two functional elements are arranged facing each other and a thin shield plate is provided between the two functional elements.

The shield plate of Japanese Unexamined Patent Application Publication No. 2000-236230 is supported by solder bumps so as to be parallel to a surface of a substrate on which the two functional elements are arranged. Further, Japanese Unexamined Patent Application Publication No. 2000-236230 describes that it is preferable for the surface acoustic wave filter to have a small height and size, and that the thickness of the shield plate is, for example, 0.1 to 0.5 mm.

In an acoustic wave module provided with the above shield plate, the shape of the shield plate changes due to, for example, the ambient temperature or the internal stress generated in the shield plate, thus changing the relative positional relationship between the shield plate and functional elements, which affects the characteristics of the surface acoustic wave filter.

### SUMMARY OF THE INVENTION

Example embodiments of the present invention provide acoustic wave modules including functional elements and a shield layer that are each able to reduce or prevent changes in the relative positional relationship between the functional elements and the shield layer.

An acoustic wave module according to an example embodiment of the present invention includes a first portion, a first functional element, a support layer, a second portion, a second functional element, and a shield layer. The first portion includes a first surface. The first functional element is included in a first acoustic wave device and is provided on the first surface. The support layer is provided on the first surface around a region where the first functional element is located. The second portion includes a second surface, the second surface being located at a position opposite to the first surface. The second functional element is included in a second acoustic wave device and is located on the second surface. The shield layer includes a first peripheral end portion and a second peripheral end portion, the first peripheral end portion and the second peripheral end portion being connected to the first surface to cover the first functional element. A hollow space is defined by the first portion, the second portion, and the support layer, and the first functional element, the second functional element and the shield layer are arranged in the hollow space. The shield layer includes a first layer provided on a first functional element side and a second layer provided on a second functional element side. The second layer adds, to the first layer, a force that causes the first layer to warp so that the first layer at the first peripheral end portion and second peripheral end portion approaches the first functional element.

According to example embodiments of the present invention, in acoustic wave devices each including a functional element provided on a first surface of a first portion and a shield layer covering the functional element, a first peripheral end portion and a second peripheral end portion of the shield layer are connected to the first surface. The shield layer includes a first layer and a second layer, the second layer, which is an outer layer far from the functional element, adds, to the first layer, a force that causes the first layer to warp in a direction in which the first layer at the first peripheral end portion and the second peripheral end portion approaches the functional element. Thus, the first layer is fixed by the force added by the second layer, so that changes in the relative positional relationship between the functional element and the shield layer can be reduced or prevented.

The above and other elements, features, steps, characteristics and advantages of the present invention will become more apparent from the following detailed description of the example embodiments with reference to the attached drawings.

### BRIEF DESCRIPTION OF THE DRAWINGS

FIGS. 1A and 1B are a cross-sectional view and a plan view of an acoustic wave module according to Example Embodiment 1 of the present invention.

FIG. 2 is an enlarged view of a shield layer in FIGS. 1A and 1B.

FIG. 3 is a view showing a shield layer of an acoustic wave module of Comparative Example 1.

FIG. 4 is a cross-sectional view taken along line B-B of FIGS. 1A and 1B.

FIGS. 5A to 5E are first views for explaining an example of a manufacturing process of the acoustic wave module in Example Embodiment 1 of the present invention.

FIGS. 6F and 6G are second views for explaining the example of the manufacturing process of the acoustic wave module in Example Embodiment 1 of the present invention.

FIG. 7 is an enlarged view of a shield layer in Variation 1.

FIG. 8A and FIG. 8B are a cross-sectional view and a plan view of an acoustic wave module in Example Embodiment 2 of the present invention.

FIG. 9 is an enlarged view of a shield layer and a piezoelectric body in FIG. 7.

FIG. 10 is a view showing an acoustic wave module of Comparative Example 2.

### DETAILED DESCRIPTION OF THE EXAMPLE EMBODIMENTS

The example embodiments of the present invention will be described in detail below with reference to the accompanying drawings. The same or equivalent portions or components in the drawings are denoted by the same reference signs and their descriptions are not repeated.

### Example Embodiment 1

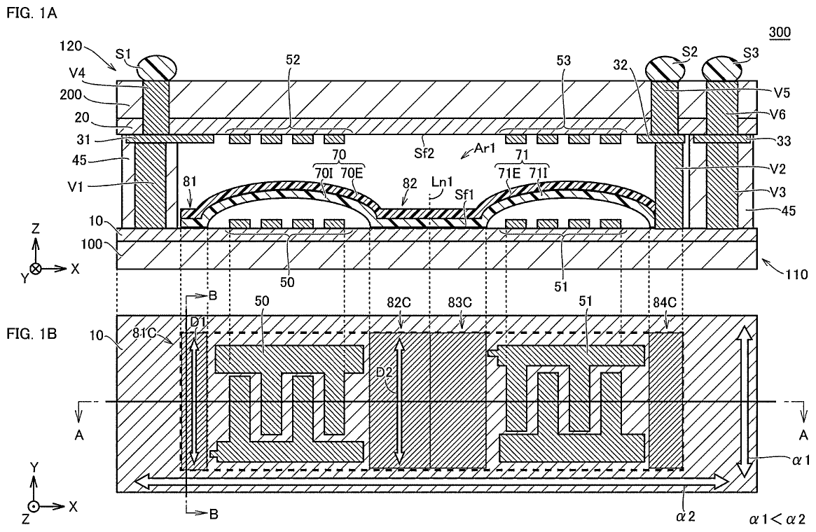

FIGS. 1A and 1B is a cross-sectional view of an acoustic wave module 300 including acoustic wave devices 110 and 120 of Example Embodiment 1 and a plan view of the acoustic wave module 300. FIG. 1A is a cross-sectional view taken along line A-A of FIG. 1B. Although each of the acoustic wave devices 110 and 120 in the present example embodiment will be described as an example of a surface acoustic wave device that includes an IDT (Inter Digital Transducer) electrode as a functional element, the acoustic wave device may also use a bulk wave or a boundary acoustic wave.

In the following description, the thickness direction of piezoelectric body support substrates 100 and 200 is defined as the Z-axis direction, and a plane perpendicular or substantially perpendicular to the Z-axis direction is defined by the X axis and the Y axis. The positive direction of the Z axis in each drawing may be referred to as the upper side and the negative direction of the Z axis may be referred to as the lower side.

As shown in FIG. 1A, the acoustic wave module 300 includes the acoustic wave device 110 and the acoustic wave device 120. The acoustic wave device 110 includes the piezoelectric body support substrate 100, a piezoelectric body 10, functional elements 50 and 51, and shield layers 70 and 71. The acoustic wave device 120 includes the piezoelectric body support substrate 200, a piezoelectric body 20, functional elements 52 and 53, wiring patterns 31 to 33, through electrodes V1 to V6, solder bumps S1 to S3, and a support layer 45. The solder bump S2 is connected to the ground electrode (GND electrode) of the acoustic wave device 110 and the acoustic wave device 120. The piezoelectric body support substrate 100 and the piezoelectric body 10, and the piezoelectric body support substrate 200 and the piezoelectric body 20 define a piezoelectric substrate.

As shown in FIG. 1A, each of the through electrodes V1 to V3 of the acoustic wave device 120 is connected to the acoustic wave device 110, thus electrically connecting the acoustic wave device 110 and the acoustic wave device 120.

The acoustic wave device 110 and the acoustic wave device 120 are located so that a main surface Sf1 of the piezoelectric body 10 on the positive direction side and a main surface Sf2 of the piezoelectric body 20 on the negative direction side oppose each other. The support layer 45, which is made of, for example, a resin, is arranged between the piezoelectric body 10 and the piezoelectric body 20 to surround the functional elements 50 to 53. That is, the support layer 45 is provided around a region where the functional element 50 is located. As a result, a hollow space Ar1 is defined by the piezoelectric body 10, the piezoelectric body 20, and the support layer 45. In the acoustic wave devices 110 and 120, surface acoustic waves propagate in the piezoelectric bodies 10 and 20 adjacent to the hollow space Ar1.

The piezoelectric bodies 10 and 20 are preferably made of, for example, a piezoelectric single crystal material such as lithium tantalate (LiTaO3), lithium niobate (LiNbO3), or sapphire, or a piezoelectric multilayer material composed of LiTaO3 or LiNbO3. On the other hand, the piezoelectric body support substrates 100 and 200 are, for example, silicon substrates or the like. The piezoelectric body 10 may correspond to the “first portion”. The piezoelectric body 20 may correspond to the “second portion”.

The functional elements 50 and 51 are provided on the main surface Sf1 of the piezoelectric body 10. The functional elements 52 and 53 are provided on the main surface Sf2 of the piezoelectric body 20. When viewed in a plan view from the positive direction side of the Z axis, the functional element 50 and the functional element 52 at least partially overlap. Similarly, when viewed in a plan view from the positive direction side of the Z axis, the functional element 51 and the functional element 53 at least partially overlap.

A pair of Interdigital Transducer (IDT) electrodes formed using an electrode material is included as the functional elements 50 to 53. Examples of the electrode material include a single metal including at least one of aluminum, copper, silver, gold, titanium, tungsten, platinum, chromium, nickel, and molybdenum, and an alloy mainly composed of these metals. The piezoelectric body 10 and the functional elements 50 and 51 define a surface acoustic wave resonator. The piezoelectric body 20 and the functional elements 52 and 53 define a surface acoustic wave resonator. The wiring patterns 31 to 33 and through electrodes V1 to V6, which are conductive, are made of, for example, a metal such as copper or aluminum.

As shown in FIG. 1A, the functional elements 50 and 51 of the acoustic wave device 110 are covered by the shield layers 70 and 71 each having a flat shape. Although Example Embodiment 1 shows an example in which the shield layer 70 and the shield layer 71 are integrally molded, they may be provided separately as long as each of the shield layer 70 and the shield layer 71 is connected to the ground electrode. That is, the shield layer 70 and the shield layer 71 may be divided, for example, at the dashed line Ln1. As shown in FIG. 1A, when the shield layers 70 and 71 are viewed from the positive direction side of the Y axis, each of the shield layers 70 and 71 has an arch shape.

Each of the shield layers 70 and 71 in Example Embodiment 1 preferably has a tunnel shape, for example. That is, each of the shield layers 70 and 71 has the same cross-sectional view as in FIG. 1A in any cross section in the Y-axis direction. In other words, even if the position of line A-A in FIG. 1B is shifted parallel or substantially parallel to either the positive direction side or negative direction side of the Y-axis direction, the shape of the respective cross sections of the shield layers 70 and 71 will be the same or substantially the same as the arch shape shown in FIG. 1A. That is, in Example Embodiment 1, each of the shield layers 70 and 71 includes two openings, one on the positive direction side of the Y axis and the other on the negative direction side of the Y axis.

Each of the shield layers 70 and 71 preferably includes at least two layers. Specifically, the shield layer 70 includes a first layer 70I on the inner side and a second layer 70E on the outer side. Similarly, the shield layer 71 includes a first layer 71I on the inner side and a second layer 71E on the outer side. The first layers 70I and 71I are located in the inner side portions of the arch-shaped shield layers 70 and 71. In other words, the first layers 70I and 71I are located on the sides of the functional elements 50 and 51, respectively. The second layers 70E and 71E are located in the outer side portion of the arch-shaped shield layers 70 and 71. In other words, the second layers 70E and 71E are located on the sides of the functional elements 52 and 53, respectively.

As shown in FIG. 1A, the shield layer 70 includes a peripheral end portion 81 on the negative direction side of the X axis and a peripheral end portion 82 on the positive direction side of the X axis. FIG. 1B shows a plan view of the piezoelectric body 10 and the functional elements 50 and 51 from the positive direction side of the Z axis. A contact surface 81C is the contact surface between the peripheral end portion 81 and the piezoelectric body 10 in FIG. 1A. The contact surface 81C has a rectangular or substantially rectangular shape extending in the Y-axis direction. In other words, a longitudinal direction D1 of the contact surface 81C is the same or substantially the same direction as the Y-axis direction. A contact surface 82C is the contact surface between the peripheral end portion 82 and the piezoelectric body 10 in FIG. 1A. The contact surface 82C has a rectangular or substantially rectangular shape extending in the Y-axis direction. In other words, a longitudinal direction D2 of the contact surface 82C is the same or substantially the same direction as the Y-axis direction.

Thus, the shield layer 70, which has a flat shape, covers the functional element 50 by connecting the peripheral end portion 81 and the peripheral end portion 82 to the main surface Sf1. Thus, the shield layer 70 defines an arch shape with its apex on the positive direction side of the Z axis to suppress or minimize interference of the functional element 50 with other configurations. The shield layer 71 also preferably includes two peripheral end portions, and the two peripheral end portions of the shield layer 71 also contact the piezoelectric body 10 at contact surfaces 83C and 84C. The contact surfaces 83C and 84C also have a rectangular shape extending in the Y-axis direction. The shape of the contact surfaces 81C to 84C is not limited to a rectangular or substantially rectangular shape, but may be other shapes such as, for example, an oval shape.

FIG. 1B shows the linear expansion coefficient of the piezoelectric body 10 that varies with temperature. The piezoelectric body 10 has different linear expansion coefficients in the X-axis direction and the Y-axis direction. As shown in FIG. 1B, the linear expansion coefficient of the piezoelectric body 10 in the Y-axis direction is a linear expansion coefficient α1, and the linear expansion coefficient of the piezoelectric body 10 in the X-axis direction is a linear expansion coefficient α2. In the piezoelectric body 10 of Example Embodiment 1, the linear expansion coefficient α1 in the Y-axis direction of the main surface Sf1 is smaller than the linear expansion coefficient α2 in the X-axis direction. The direction of the linear expansion coefficient α1 is the direction with the smallest linear expansion coefficient in the piezoelectric body 10, and the direction of the linear expansion coefficient α2 is the direction with the largest linear expansion coefficient in the piezoelectric body 10. As shown in FIG. 1B, the longitudinal direction D1 of the contact surface 81C and the longitudinal direction D2 of the contact surface 82C in Example Embodiment 1 are directions along the Y axis. In other words, the peripheral end portion 81 and the peripheral end portion 82 having a longitudinal direction are connected to the piezoelectric body 10 along the Y-axis direction.

### Two-Layer Structure of Shield Layer

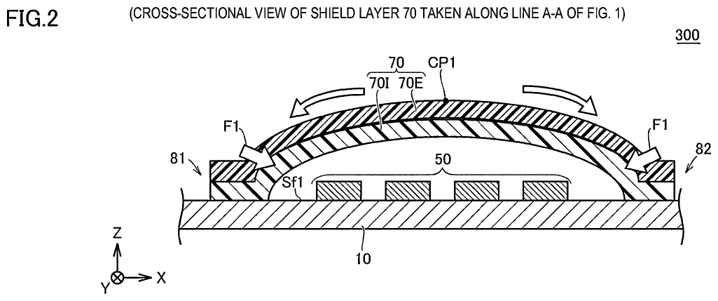

FIG. 2 is an enlarged view of the shield layer 70 in FIG. 1A. FIG. 2 shows the shield layer 70, the functional element 50, and the piezoelectric body 10. As shown in FIG. 2, the shield layer 70 includes the second layer 70E on the outer side and the first layer 70I on the inner side. In the acoustic wave module 300 of Example Embodiment 1, the linear expansion coefficient of the second layer 70E on the outer side is greater than the linear expansion coefficient of the first layer 70I on the inner side.

Since the linear expansion coefficient of the second layer 70E is greater than the linear expansion coefficient of the first layer 701, the second layer 70E expands more than the first layer 70I when temperature changes occur in the shield layer 70. When the second layer 70E thermally expands, the first layer 70I is pulled by the expanding second layer 70E due to a frictional force generated between the second layer 70E and the first layer 70I, so that a force to expand in the same manner as the second layer 70E is generated in the first layer 70I. On the other hand, a force to hold the shape of the first layer 70I is also generated in the first layer 70I.

Thus, the second layer 70E adds, to the first layer 70I, a force that causes the first layer 70I to warp so that the first layer 70I at the peripheral end portion 81 and the peripheral end portion 82 approaches the functional element 50. In other words, a compressive stress is generated in the flat-shaped shield layer 70 such that the shield layer 70 bulges and warps toward the functional element 52 with a center point CP1 as the apex when the second layer 70E on the outer side is viewed in plan view from the positive direction side of the Z axis. Therefore, in Example Embodiment 1, a force F1 directed toward the functional element 50 is generated in the first layer 70I at the peripheral end portions 81 and 82, as shown in FIG. 2.

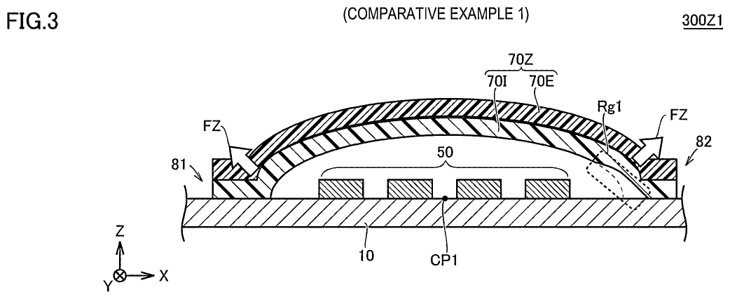

FIG. 3 is a view showing a shield layer 70Z of an acoustic wave module 300Z1 in Comparative Example 1. As shown in FIG. 3, in the shield layer 70Z, unlike Example Embodiment 1, the linear expansion coefficient of the second layer 70E on the outer side is smaller than the linear expansion coefficient of the first layer 70I on the inner side. Therefore, in the acoustic wave module 300Z1 in Comparative Example 1, a force FZ to move away from the functional element 50 is generated at the peripheral end portions 81 and 82 of the shield layer 70, as shown in FIG. 3. In other words, in Comparative Example 1, the second layer 70E on the outer side defines and functions as a tensile stress layer.

As a result, the force FZ in the opposite direction of F1 shown in FIG. 2 is generated in the first layer 70I, and the shape of a portion of the first layer 70I can change, as shown in a region Rg1. When the shape of the first layer 70I partially changes, the relative positional relationship between the functional element 50 and the shield layer 70Z changes, and the capacitance component between the functional element 50 and the shield layer 70Z changes. Therefore, in Comparative Example 1, the characteristics of the functional element 50 may unintentionally change from the design characteristics. Further, the force FZ can be a factor that causes the shield layer 70Z to peel away from the main surface Sf1.

As described with reference to FIG. 2, in the acoustic wave module 300 of Example Embodiment 1, the linear expansion coefficient of the second layer 70E is greater than the linear expansion coefficient of the first layer 70I, and a force is added to the first layer 70I by the second layer 70E to cause the first layer 70I to warp so that the peripheral end portion 81 and the peripheral end portion 82 approach the functional element 50. Thus, since the force F1 shown in FIG. 2 is generated to allow the first layer 70I to maintain its arch shape, changes in the relative positional relationship between the functional element 50 and the shield layer 70 can be suppressed or minimized. Further, since the force F1 pressing the main surface Sf1 from the outside to the inside is generated at the peripheral end portions 81 and 82 of the shield layer 70, the adhesion between the shield layer 70 and the main surface Sf1 is improved, so that the shield layer 70 can be fixed to the piezoelectric body 10.

### Linear Expansion Coefficient of Piezoelectric Body and Contact Surface

As described with reference to FIG. 1B, the linear expansion coefficient α1 of the piezoelectric body 10 in the Y-axis direction is smaller than the linear expansion coefficient α2 of the piezoelectric body 10 in the X-axis direction. The longitudinal directions D1 and D2 of the contact surfaces 81C and 82C are along the Y axis. In other words, the shield layer 70 in Example embodiment 1 is arranged so that the longitudinal directions D1 and D2 of the contact surfaces 81C and 82C are along the Y-axis direction, in which the linear expansion coefficient is smaller, in the piezoelectric body 10.

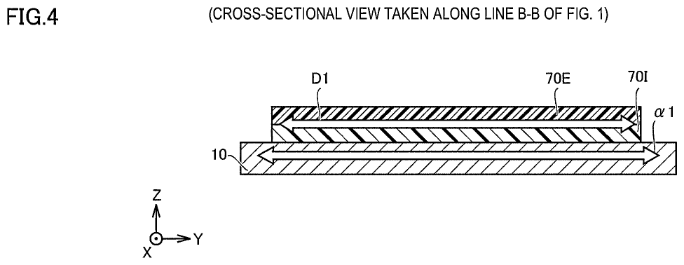

FIG. 4 is a cross-sectional view taken along line B-B in FIG. 1B. As shown in FIG. 1B, the longitudinal direction D1 of the contact surface 81C is in the same direction as the linear expansion coefficient α1, which is smaller than the linear expansion coefficient α2. Therefore, the acoustic wave module 300 in Example Embodiment 1 can reduce the friction generated between the piezoelectric body 10 and the shield layer 70 at the contact surface 81C when the piezoelectric body 10 expands or contracts due to temperature change. Thus, in the acoustic wave module 300 of Example Embodiment 1, it is possible to suppress or minimize the shield layer 70 from peeling off the piezoelectric body 10 caused by strong friction generated between the shield layer 70 and the piezoelectric body 10 due to the temperature change.

### Manufacturing Process

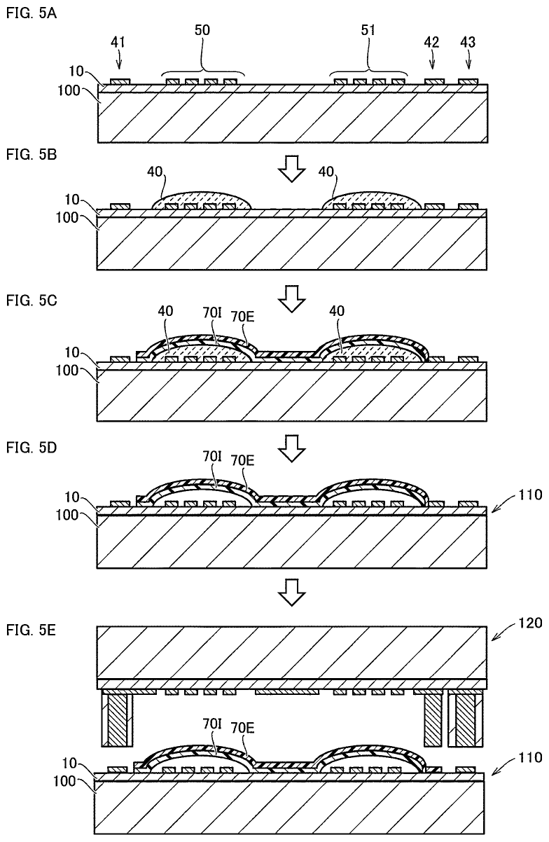

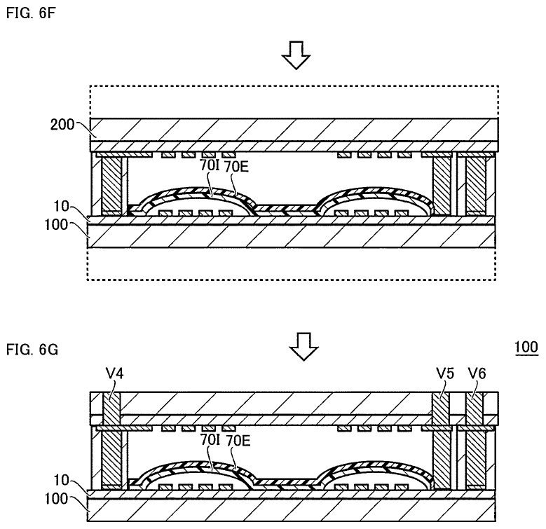

FIGS. 5A to 5E are first views for explaining an example of a manufacturing process of the acoustic wave module 300 in Example Embodiment 1. FIGS. 6F and 6G are second views for explaining the example of the manufacturing process of the acoustic wave module 300 in Example Embodiment 1. As shown in FIG. 5A, wiring patterns 41 to 43 and the functional elements 50 and 51 are provided on the piezoelectric body 10. The wiring patterns 41 to 43 are a conductive metal such as, for example, copper or aluminum or a Sn—Ag alloy. The piezoelectric body 10 is provided on the main surface of the piezoelectric body support substrate 100 using a thin-film formation process such as sputtering.

Then, as shown in FIG. 5B, a sacrificial layer 40 is formed to form the shield layers 70 and 71. The sacrificial layer 40 is formed by a positive photoresist, and the sacrificial layer 40 is preferably made of, for example, a novolac resin. As shown in FIG. 5B, the sacrificial layer 40 is disposed in the inner portion of the shield layer 70, which has a tunnel shape. More specifically, the sacrificial layer 40 is formed by exposing and developing the photoresist via a photomask having a predetermined pattern formed thereon.

Then, as shown in FIG. 5C, the shield layer 70, which includes the first layer 70I and the second layer 70E, is formed. The shield layer 70 is formed, for example, by using a lift-off method after the first layer 70I and the second layer 70E are formed by vapor deposition. The first layer 70I is based on Ti, for example. The linear expansion coefficient of the first layer 70I is, for example, about 8.6×10⁻⁶/K. The second layer 70E is based on Cu, for example. The linear expansion coefficient of the second layer 70E is, for example, about 16.5×10⁻⁶/K. In other words, the linear expansion coefficient of the second layer 70E is greater than the linear expansion coefficient of the first layer 70I.

The number of layers included in the shield layer 70 of Example Embodiment 1 is not limited to two layers, and the shield layer 70 may include three or more layers. In an acoustic wave module 300 in which the shield layer 70 includes three or more layers, the shield layer 70 includes a plurality of interlayers. In the shield layer 70 that includes three or more layers, the layers are formed so that, between the layers adjacent to each other, the linear expansion coefficient of the outer layer is greater than the linear expansion coefficient of the inner layer. In other words, the shield layer 70 can be formed so that the linear expansion coefficient increases in a stepwise manner from the inside to the outside.

When three or more layers are included, it is possible to partially include interlayer(s) having a relationship where the linear expansion coefficient of the outer layer is less than the linear expansion coefficient of the inner layer. In such a case, the shield layer 70 is formed so that among the plurality of interlayers, the number of interlayers having a relationship where the linear expansion coefficient of the outer layer is greater than the linear expansion coefficient of the inner layer is more than the number of interlayers having a relationship where the linear expansion coefficient of the outer layer is less than the linear expansion coefficient of the inner layer.

Then, as shown in FIG. 5D, the sacrificial layer 40 is removed using, for example, a peeling liquid, so that the acoustic wave device 110 is formed. Further, as shown in FIG. 5E, the acoustic wave device 110 and the acoustic wave device 120 are bonded using a bonding material. As shown in FIG. 6F, the thickness of the acoustic wave module 300 is reduced by grinding the piezoelectric body support substrates 100 and 200. Finally, as shown in FIG. 6G, the through electrodes V4 to V6 and the solder bumps S1 to S3 are formed, thus completing the manufacture of the acoustic wave module 300.

### Variation 1

In Example Embodiment 1, a configuration in which the piezoelectric body 10 and the first layer 70I are in contact is described. However, an intermediate layer may be disposed between the piezoelectric body 10 and the first layer 70I. Variation 1 describes an example in which an insulating layer 80, as the intermediate layer, is provided between the piezoelectric body 10 and the first layer 70I.

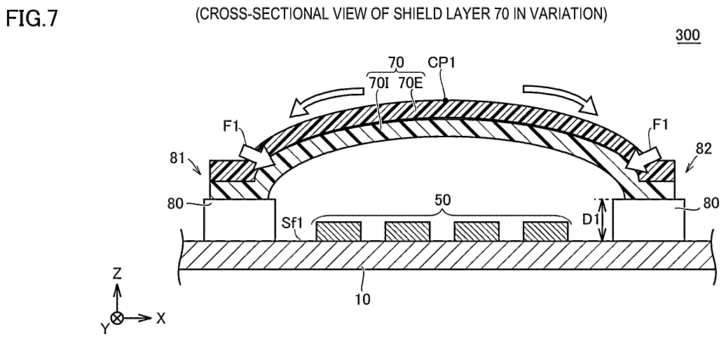

FIG. 7 is an enlarged view of the shield layer 70 in Variation 1. As shown in FIG. 7, the insulating layer 80 is provided between the piezoelectric body 10 and the first layer 70I at the peripheral end portion 81 and the peripheral end portion 82.

The base material of the insulating layer 80 can be, for example, a resin containing an organic material, or an insulating inorganic material. The organic material includes, for example, at least one of polyimide, epoxy-based resin, cyclic olefin-based resin, benzocyclobutene, polybenzoxazole, phenolic resin, silicone, and acrylic resin. The insulating inorganic material includes, for example, at least one of silicon oxide or silicon nitride.

As shown in FIG. 7, the height of the insulating layer 80 in the Z-axis direction is a distance D1. The distance between the shield layer 70 and the functional element 50 in Variation 1 is longer than the distance between the shield layer 70 and the functional element 50 in Example Embodiment 1 by the distance D1. Thus, in the acoustic wave module of Variation 1, the distance between the shield layer 70 and the functional element 50 can be adjusted by arranging an intermediate layer between the piezoelectric body 10 and the first layer 70I.

### Variation 2

In Example Embodiment 1, an example is described in which the linear expansion coefficient of the second layer 70E on the outer side is greater than the linear expansion coefficient of the first layer 70I on the inner side, thus generating a force that causes the first layer 70I to warp so that the first layer 70I at the peripheral end portion 81 and the peripheral end portion 82 approaches the functional element 50. However, when the second layer 70E on the outer side functions as a compressive stress layer with respect to the first layer 70I on the inner side, regardless of the linear expansion coefficient, it generates a force F1 that causes the peripheral end portions 81 and 82 to move toward the center point CP1. In Variation 2, the second layer 70E on the outer side is formed by, for example, sputtering, and thus the second layer 70E on the outer side functions as a compressive stress layer.

Since the second layer 70E on the outer side is formed by sputtering, it defines and functions as a compressive stress layer that generates compressive stress in the first layer 70I on the inner side. When formed by sputtering, the second layer 70E is formed by collision of the target with ionized argon or the like so that the sputtering atoms of the second layer 70E are incident on the first layer 70I.

At this time, not only sputtering atoms but also argon cations, which are neutralized at a certain rate and reflected, are incident on the first layer 70I in a state having kinetic energy. As a result, high energy argon penetrates between the crystal lattices in the first layer 70I, pushing the lattice spacing apart and generating compressive stress. In other words, as in Example Embodiment 1, a force is generated in the first layer 70I to cause it to warp so that the first layer 70I at the peripheral end portion 81 and the peripheral end portion 82 approaches the functional element 50. When the compressive stress layer is formed using sputtering, as in Variation 2, the base material of the second layer 70E is Cu, Au or the like, and the base material of the first layer 70I is, for example, Ti, Ni or the like, for example.

In the acoustic wave module 300 of Variation 2, the force F1 shown in FIG. 2 is also generated between the peripheral end portion 81 and the peripheral end portion 82. Thus, even in Variation 2, since the first layer 70I can maintain the arch shape without changing its shape, changes in the relative positional relationship between the functional element 50 and the shield layer 70 can be reduced or prevented. Further, since the force F1 that presses on the main surface Sf1 from the outside toward the inside is generated at the peripheral end portions 81 and 82 of the shield layer 70, the adhesion between the shield layer 70 and the main surface Sf1 can be improved also in Variation 2.

The method of forming the compressive stress layer is not limited to sputtering, but may be, for example, electric field plating film. When the compressive stress layer is formed by electric field plating film, for example, a Cu film is formed as a plating film on the sacrificial layer 40 on which a Ti film serving as the first layer 70I has been formed. At this time, additives added to the plating solution are adjusted so that the Cu film defining and functioning as the second layer 70E becomes a compressive stress layer. The thickness of the Cu film defining and functioning as the second layer 70E and the thickness of the Ti film defining and functioning as the first layer 70I are also adjusted so that the Cu film becomes a desired compressive stress layer. The base material of the second layer 70E is not limited to Cu, but may be, for example, Ni (nickel). The compressive stress layer may also be formed by, for example, electron beam deposition, electroless plating, CVD (Chemical Vapor Deposition), thermal spraying, or the like.

### Example Embodiment 2

In Example Embodiment 1, a configuration is described in which the longitudinal directions D1 and D2 of the contact surfaces 81C and 82C are in the same or substantially the same direction as the linear expansion coefficient α1, and the linear expansion coefficient α1 is smaller than the linear expansion coefficient α2 (α1<α2). In Example Embodiment 2 of the present invention, a configuration is to be described in which the arrangement direction of the main surface Sf1 is changed and the positional relationship between the linear expansion coefficient α1 and the linear expansion coefficient α2 is reversed.

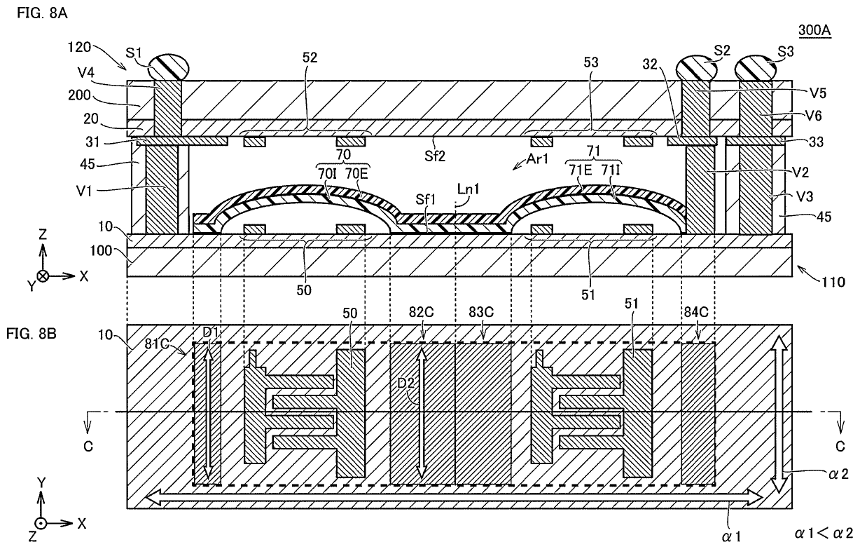

FIGS. 8A and 8B show cross-sectional views (FIG. 8A) of acoustic wave devices 110 and 120 in Example Embodiment 2 and a plan view (FIG. 1B) of the acoustic wave device 110 in FIG. 8A. FIG. 8A is a cross-sectional view taken along line C-C of FIG. 8B. The description of the configurations in FIGS. 8A and 8B that overlap with the acoustic wave module 300 in FIGS. 1A and 1B will not be repeated.

In the piezoelectric body 10 of Example Embodiment 1, the linear expansion coefficient α1 is smaller than the linear expansion coefficient α2, and the linear expansion coefficient α1 is the linear expansion coefficient in the Y-axis direction and the linear expansion coefficient α2 is the linear expansion coefficient in the X-axis direction. In a piezoelectric body 10 of Example Embodiment 2, while a linear expansion coefficient α1 is smaller than a linear expansion coefficient α2, the linear expansion coefficient α1 is the linear expansion coefficient in the X-axis direction and the linear expansion coefficient α2 is the linear expansion coefficient in the Y-axis direction. That is, the piezoelectric body 10 of Example Embodiment 2 is arranged by tilting the arrangement of the piezoelectric body 10 of Example Embodiment 1 by 90 degrees. In other words, the direction of linear expansion coefficient α1 and the direction of linear expansion coefficient α2 are exchanged from Example Embodiment 1.

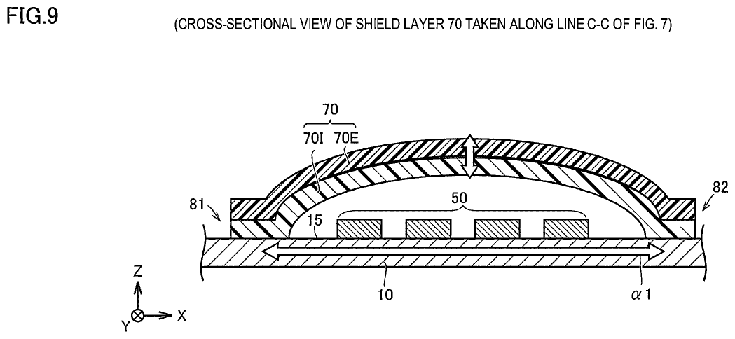

FIG. 9 is an enlarged view of the shield layer 70 and the piezoelectric body 10 in FIG. 8A. As shown in FIG. 8B, the linear expansion coefficient α1 of the piezoelectric body 10 in the X-axis direction is smaller than the linear expansion coefficient α2 of the piezoelectric body 10 in the Y-axis direction. As shown in FIG. 8B, longitudinal directions D1 and D2 of the contact surfaces 81C and 82C are along the Y-axis direction, in which the linear expansion coefficient of the piezoelectric body 10 is the linear expansion coefficient of that is greater than the linear expansion coefficient α1. In other words, the shield layer 70 in Example Embodiment 2 is arranged so that the direction that is perpendicular or substantially perpendicular to the longitudinal directions D1 and D2 (X-axis direction) on the main surface Sf1 is along the X-axis direction in which the linear expansion coefficient of the piezoelectric body 10 is smaller. Therefore, as shown in FIG. 9, the linear expansion coefficient of the shield layer 70, which has a tunnel shape, in a direction from the peripheral end portion 81 to the peripheral end portion 82 is the linear expansion coefficient α1.

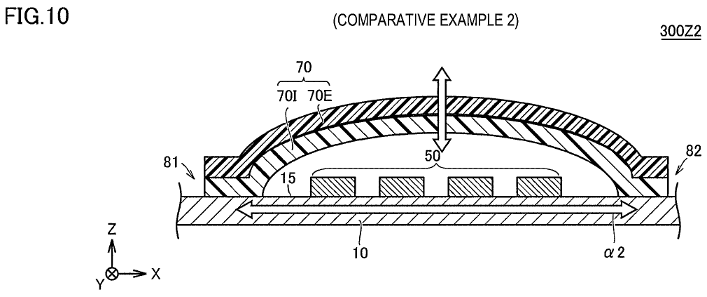

FIG. 10 is a view showing an acoustic wave module 300Z2 of Comparative Example 2. In the acoustic wave module 300Z2 of Comparative Example 2, the linear expansion coefficient in a direction from the peripheral end portion 81 to the peripheral end portion 82 is the linear expansion coefficient α2. When the linear expansion coefficient in the X-axis direction, which is a direction forming a right angle with the longitudinal directions D1 and D2 of the contact surfaces 81C and 82C, is larger, changes in the positions of the peripheral end portion 81 and the peripheral end portion 82 of the shield layer 70 increase due to the expansion and contraction of the piezoelectric body 10. In other words, as shown in FIG. 10, the movement width of the apex of the shield layer 70 in the Z-axis direction increase. As a result, in Comparative Example 2, the relative positional relationship between the functional element 50 and the shield layer 70 changes, the capacitance component between the functional element 50 and the shield layer 70 changes, and the characteristics of the functional element 50 may unintentionally change from the characteristics when designed.

In contrast, in Example Embodiment 2, as shown in FIG. 9, the linear expansion coefficient in the X-axis direction, which is perpendicular or substantially perpendicular to the longitudinal directions D1 and D2 of the contact surfaces 81C and 82C, is smaller. Thus, in an acoustic wave module 300A according to Example Embodiment 2, deformation of the arch shape can be reduced or prevented before and after the expansion and contraction of the piezoelectric body 10, so that changes in the relative positional relationship between the functional element 50 and the shield layer 70 can be reduced or prevented.

Further, in Example Embodiment 2, in the functional element 50 including the IDT electrode, the propagation direction of the signal propagating through the piezoelectric body 10 is in the Y-axis direction. Thus, interference to the signal propagating through the piezoelectric body 10 can be reduced or prevented by the contact surfaces 81C, 82C between the shield layer 70 and the piezoelectric body 10.

As in Example Embodiment 1, since the shield layer 70 includes the second layer 70E with a larger linear expansion coefficient and the first layer 70I with a smaller linear expansion coefficient than the second layer 70E, a force is added to the first layer 70I by the second layer 70E to cause the first layer 70I to warp so that the peripheral end portion 81 and the peripheral end portion 82 approach the functional element 50. Thus, since the first layer 70I can maintain its arch shape, changes in the relative positional relationship between the functional element 50 and the shield layer 70 can be reduced or prevented.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave module comprising:
a first portion including a first surface;
a first functional element provided on the first surface and included in a first acoustic wave device;
a support layer provided on the first surface around a region where the first functional element is located;
a second portion including a second surface, the second surface being located at a position opposite to the first surface;
a second functional element provided on the second surface and included in a second acoustic wave device; and
a shield layer including a first peripheral end portion and a second peripheral end portion, the first peripheral end portion and the second peripheral end portion being connected to the first surface to cover the first functional element; wherein
a hollow space is defined by the first portion, the second portion and the support layer, and the first functional element, the second functional element and the shield layer are located in the hollow space;
the shield layer includes a first layer provided on a first functional element side and a second layer provided on a second functional element side; and
the second layer adds, to the first layer, a force that causes the first layer to warp so that the first layer at the first peripheral end portion and second peripheral end portion approaches the first functional element.

2. The acoustic wave module according to claim 1, wherein a linear expansion coefficient of the second layer is greater than a linear expansion coefficient of the first layer.

3. The acoustic wave module according to claim 1, wherein the second layer defines and functions as a compressive stress layer.

4. The acoustic wave module according to claim 1, wherein
in the first portion, a linear expansion coefficient in a first direction, which is perpendicular or substantially perpendicular to a normal direction of the first surface, is smaller than a linear expansion coefficient in a second direction, which is perpendicular or substantially perpendicular to the normal direction and the first direction; and
a longitudinal direction of a contact surface between the first peripheral end portion and the first surface and a longitudinal direction of a contact surface between the second peripheral end portion and the first surface are each a direction along the first direction.

5. The acoustic wave module according to claim 1, wherein
in the first portion, a linear expansion coefficient in a first direction, which is perpendicular or substantially perpendicular to a normal direction of the first surface, is greater than a linear expansion coefficient in a second direction, which is perpendicular or substantially perpendicular to the normal direction and the first direction; and
a longitudinal direction of a contact surface between the first peripheral end portion and the first surface and a longitudinal direction of a contact surface between the second peripheral end portion and the first surface are each a direction along the first direction.

6. The acoustic wave module according to claim 5, wherein
the first functional element includes an IDT (Inter Digital Transducer) electrode; and
a propagation direction of a signal in the first functional element is the first direction.

7. An acoustic wave module comprising:
a first portion including a first surface;
a first functional element provided on the first surface and included in a first acoustic wave device;
a support layer provided on the first surface around a region where the first functional element is located;
a second portion including a second surface, the second surface being located at a position opposite to the first surface;
a second functional element provided on the second surface and included in a second acoustic wave device; and
a shield layer including a first peripheral end portion and a second peripheral end portion, the first peripheral end portion and the second peripheral end portion being connected to the first surface to cover the first functional element; wherein
a hollow space is defined by the first portion, the second portion and the support layer, and the first functional element, the second functional element and the shield layer are located in the hollow space;
in the first portion, a linear expansion coefficient in a first direction, which is perpendicular to a normal direction of the first surface, is smaller than a linear expansion coefficient in a second direction, which is perpendicular to the normal direction and the first direction; and
a longitudinal direction of a contact surface between the first peripheral end portion and the first surface and a longitudinal direction of a contact surface between the second peripheral end portion and the first surface are each a direction along the first direction.

8. An acoustic wave module comprising:
a first portion including a first surface;
a first functional element provided on the first surface and included in a first acoustic wave device;
a support layer provided on the first surface around a region where the first functional element is located;
a second portion including a second surface, the second surface being located at a position opposite to the first surface;
a second functional element provided on the second surface and included in a second acoustic wave device; and
a shield layer including a first peripheral end portion and a second peripheral end portion, the first peripheral end portion and the second peripheral end portion being connected to the first surface to cover the first functional element; wherein
a hollow space is defined by the first portion, the second portion and the support layer, and the first functional element, the second functional element and the shield layer are located in the hollow space;
in the first portion, a linear expansion coefficient in a first direction, which is perpendicular to a normal direction of the first surface, is greater than a linear expansion coefficient in a second direction, which is perpendicular to the normal direction and the first direction; and
a longitudinal direction of a contact surface between the first peripheral end portion and the first surface and a longitudinal direction of a contact surface between the second peripheral end portion and the first surface are each a direction along the first direction.

9. The acoustic wave module according to claim 1, wherein one of the first portion and the second portion is provided on a main surface of a piezoelectric body support substrate.

10. The acoustic wave module according to claim 7, wherein one of the first portion and the second portion is provided on a main surface of a piezoelectric body support substrate.

11. The acoustic wave module according to claim 8, wherein one of the first portion and the second portion is provided on a main surface of a piezoelectric body support substrate.

12. The acoustic wave module according to claim 1, wherein
the first portion and the second portion are both made of a piezoelectric single crystal material; and
when viewed in a plan view, the first functional element and the second functional element at least partially overlap.

13. The acoustic wave module according to claim 1, wherein
the first functional element and the second functional element define portions of pair of Interdigital Transducer electrodes.

14. The acoustic wave module according to claim 1, wherein
each of the first layer and the second layer has an arch shape.

15. The acoustic wave module according to claim 1, wherein
the first layer and the second layer are integrally molded together.
